(19) United States
(12) Patent Application Publication
(10) Pub. No.: US 2003/0082910 A1
(43) Pub. Date: May 1, 2003

(54) Contact improvement by employing a conductive sacrificial layer

(76) Inventor: John Walsh, Hsinchu (TW)

Correspondence Address: STEVENS, DAVIS, MILLER & MOSHER, L.L.P., Suite 850, 1615 L Street, N.W., Washington, DC, 20036, US

(21) Appl. No.: 09/984,951

(22) Filed: Oct. 31, 2001

(51) Int. Cl. H01L 21/302; H01L 21/461

(52) U.S. Cl. 438/689

(57) ABSTRACT

A method for improving contact-to-diffusion by lessening the damage caused by oxide sputtering on the contact bottom includes depositing a sacrificial thin conductive polysilicon layer into the contact hole to prevent sputtering of the exposed oxide onto the bottom of the contact-to-diffusion. The polysilicon is kept thin enough to allow maximum consumption of this sacrificial layer during a subsequent Ti-silicidation process. The poly deposition process produces a conformal layer of conductive polysilicon that is not detrimental to the integrity of the contact. A higher level of contact reliability results when this sacrificial layer is employed.

### BACKGROUND OF THE INVENTION

1. Field of the Invention

The present invention relates to the field of semiconductor fabrication processes. More particularly, the present invention relates to a fabrication method for the formation of contacts in semiconductor devices

2. Discussion of Related Art

Many prior art fabrication processes create contacts by employing direct sputtering of titanium (Ti) into the contact hole. This process has the potential, inter alia, to sputter any overhanging oxide onto the bottom of the contact, or even sputter oxide from the sidewall of the contact onto the bottom of the contact hole. This highly resistive oxide layer may be marginal, passing all wafer level and component testing only to fail in early life testing. This highly resistive contact may fail to meet customer requirements resulting in a higher customer return rate. Another negative aspect of this prior art process scheme is that voids can be observed between titanium nitride/tungsten (TiN/W) and the oxide sidewall when an irregular contact is produced due to the pre-clean treatment required for Ti deposition. These voids may cause the contact to have a higher resistance than desired.

The selection of tools for Ti deposition can be a critical factor for yield optimization in a process where the contact process is prone to oxide sputtering. To enable a selection of Ti deposition tools that maximize throughput and fabrication capacity, the process integration of contact-to-diffusion (CS) is a key area where resources are focused. The current method of integrating CS has the potential to exhibit a very high yield sensitivity to the Ti deposition tool used in the contact formation.

Another drawback of the prior art processes is that step coverage of Ti at the bottom of the contact-to-diffusion area is also a major obstacle to overcome for new technologies and tools. To ensure the absence of wormholes, the Ti coverage at the bottom of the contact must be capable of covering the corners of the contact. If this cannot be guaranteed, high levels of leakage can be observed both for array devices (0.14 synchronous dynamic RAM (SDRAM)) and for support devices (0.2, 0.17, 0.14 μm SDRAM). The most critical area is at the bottom corner of the contact opening where oxide meets Si and TiSi is absent, using prior art processes.

FIG. 1 illustrates prior art oxide sputtering 10 with metal sputtering tool. Both FIGS. 1 and 3 also illustrate the result of an overhanging contact opening, i.e., no coverage at the bottom contact corners 11. When, as illustrated in FIG. 3, an oxide layer 2 forms between a tungsten (W) layer 3 and a Ti layer 5, this is most probably due to W deposition causing damage to the oxide sidewall. Alternatively, this can result from the integration of Ti and W deposition tools. Sidewall voids 21 are illustrated in FIG. 2 and result from irregularly shaped contact holes. Weak points of contact at the bottom contact corners 20 are illustrated in FIGS. 2 and 4.

### SUMMARY OF INVENTION

Thus, an improvement to existing contact formation processes is needed that reduces early lite test (ELT) failures due to contact related failures, provides higher reliability, and is more cost efficient than purchasing a new suite of Ti sputtering tools to overcome existing tool limitations.

The present invention provides a method for improving contact-to-diffusion by lessening the damage of oxide sputtering on the contact-to-diffusion bottom. A thin conductive sacrificial polysilicon layer is deposited into the contact hole. The thin conductive polysilicon layer prevents sputtering of the exposed oxide onto the bottom of the contact-to-diffusion. The polysilicon is kept thin enough to allow maximum consumption of this sacrificial layer during a subsequent Ti-silicidation process. The thin poly deposition process produces a conformal layer of conductive polysilicon that is not detrimental to the integrity of the contact. A higher level of contact reliability results when this conductive sacrificial polysilicon layer is employed.

### BRIEF DESCRIPTION OF THE DRAWINGS

FIG. 1 illustrates the prior art results of oxide sputtering with IMP tools and overhanging contact openings.

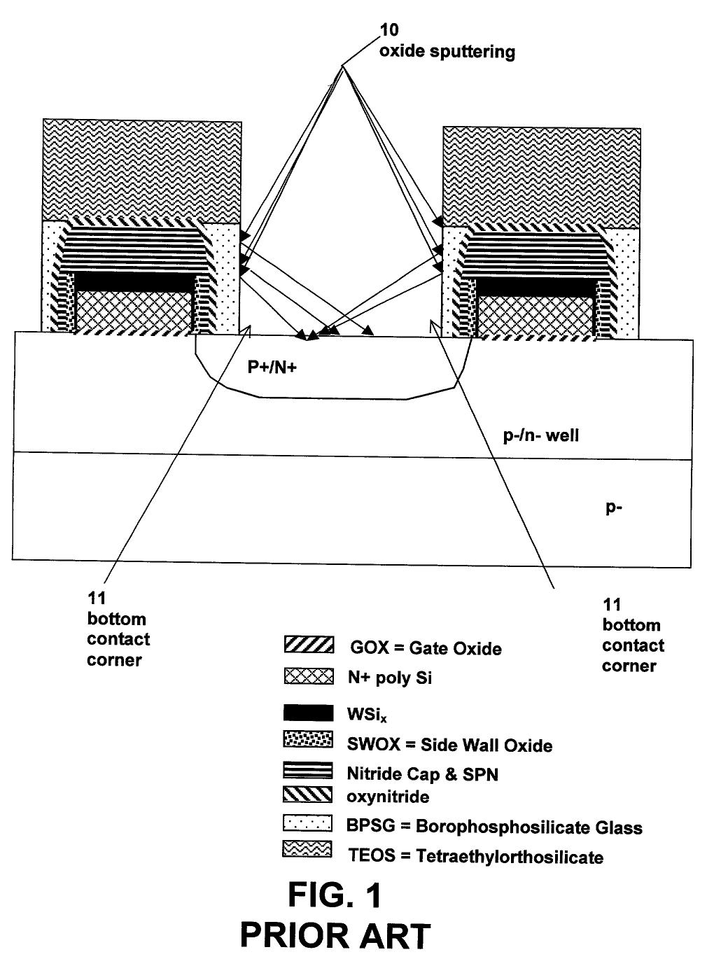

FIG. 2 illustrates the prior art sidewall voids in thin oxide layers resulting from irregular contact hole shapes and weak points of contact at the bottom corners of the contact.

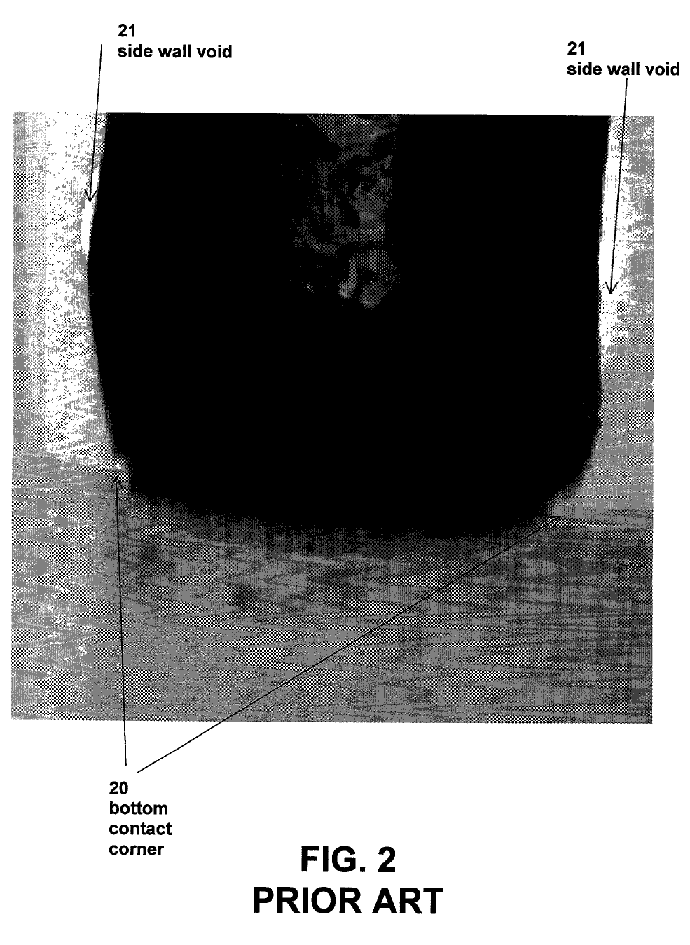

FIG. 3 illustrates the prior art thick oxide layer between W and Ti that results from oxide sputter during tungsten deposition.

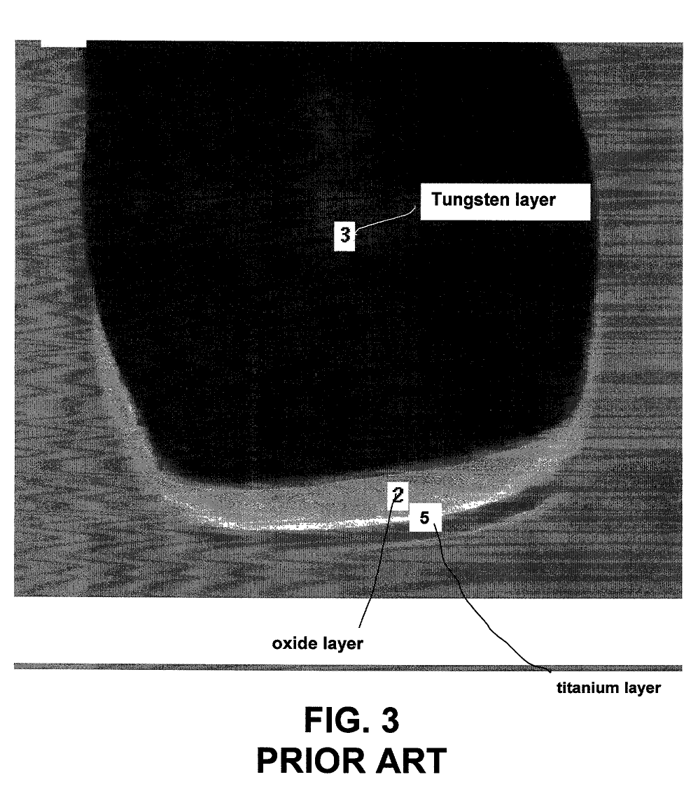

FIG. 4 illustrates prior art voids between W & TiN and weak points of contact at the bottom corners of the contact.

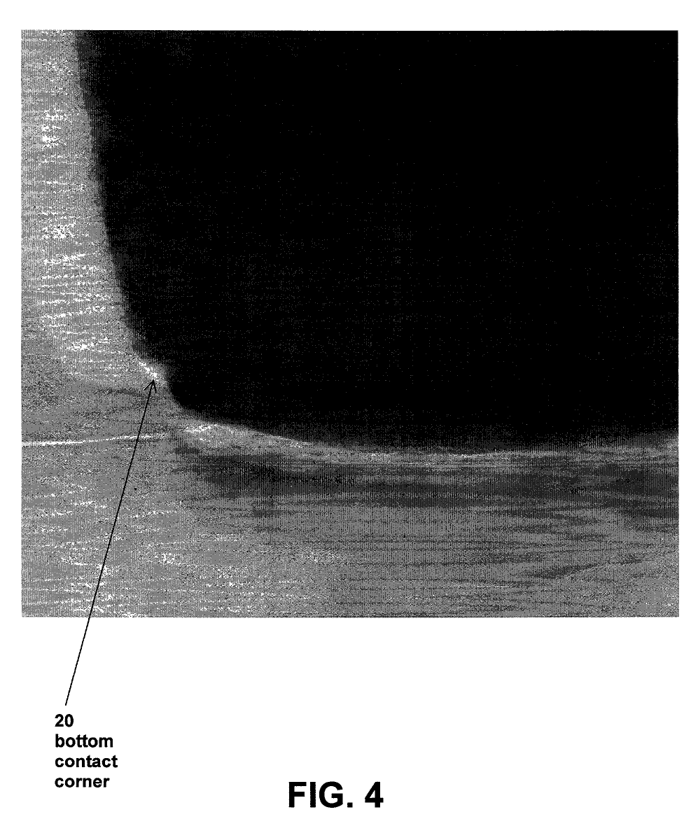

FIG. 5 illustrates a finished contact according to the contact formation method of the present invention.

### DESCRIPTION OF THE PREFERRED EMBODIMENTS

In a preferred embodiment, the present invention is integrated into a semiconductor device fabrication process after an etch of the contact holes has been completed. At this point in the fabrication process the contact and trenches have been defined in the dual damascene flow.

In a preferred embodiment, a prior art contact fabrication process, e.g., one that incorporates an Mo etch, is modified in the following way:

### Sacrificial Layer of Present Invention

1) 100 Å Poly deposition—to blanket deposit a sacrificial layer of highly conductive polysilicon in the contact holes;

Prior Art Contact formation

2) Ti liner deposition by sputtering and annealing or reactive Ti sputtering and annealing;

3) Metal Deposition;

4) Chemical mechanical polishing (CMP) (hard stop on poly without changing present CMP);

### Top Surface Cleanup of Present Invention

5) Poly etch (clear surface of poly where there are no metal lines) if hard stop on poly is preferred option; and

6) Normal Process of Record (POR).

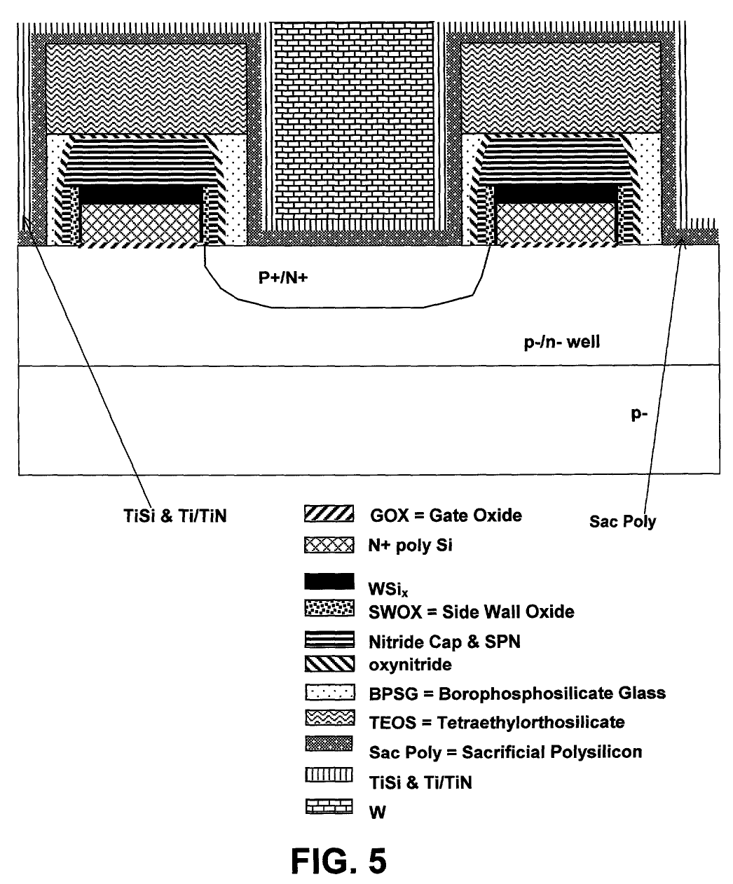

A finished contact according to the method of the present invention is illustrated FIG. 5. The sacrificial poly layer is shown at 50.

The method of contact formation according to the present invention provides many advantages over prior art methods. First, the thin sacrificial poly layer 50 acts as a conductive layer even if sputtered to the contact bottom.

The thin poly layer 50 allows TiSi formation at the weakest point of the contact and therefore reduces the risk of contact “lift-off” due to poor step coverage. “Lift-off” can be caused by either poor step coverage or by an over-aggressive metal deposition process. By employing the sacrificial layer 50 of the present invention, the likelihood of leaving voids at the contact sidewalls is also reduced as the poly deposition process is conformal and fills in any previously existing irregularly-shpaed contact sidewalls voids.

The poly layer can also act as the glue layer for the contact, eliminating the need for a pure Ti/TiN layer. The Ti layer can be deposited in a reactive sputtering manner to form TiN or the TiN can be formed by a modification to a Ti annealing step. This is an additional benefit of the sacrificial poly layer 50 in that it eliminates a two-chamber scheme for liner deposition and facilitates improved tool planning.

The chemical mechanical polishing process stops at the sacrificial poly layer 50. This layer can be used as a hard stop for CMP with a subsequent poly etch introduced to remove poly in areas without contacts.

If contact implant masks are employed, the resistance of the sacrificial poly layer 50 can be tuned to meet product source/drain (S/D) requirements.

Formation of the TiSi layer can also be individually optimized to meet product requirements.

In a preferred embodiment, the poly layer 50 must be thin enough to allow maximum consumption during TiSi formation (approximately 100 Å). The remaining poly after CMP can be removed post CMP with an etch.

It will be recognized that the above-described invention may be embodied in other specific forms without departing from the spirit or essential characteristics of the disclosure. Thus, it is understood that the invention is not to be limited by the foregoing illustrative details, but rather is to be defined by the appended claims.

What is claimed is:

1. A method for forming a contact structure having a contact bottom on a semiconductor body, said method comprising the steps of:
(a) providing a semiconductor body having a surface with contact holes etched therein;
(b) depositing a sacrificial layer on said surface with said contact holes;
(c) depositing a liner on said sacrificial layer to line said contact holes;
(d) depositing a metal layer on said liner;
(e) performing chemical mechanical polishing of said metal layer to achieve a hard stop on said sacrificial layer; and
(f) removing said sacrificial layer.

2. The method of claim 1, wherein said sacrificial layer is highly conductive polysilicon.

3. The method of claim 1, wherein said depositing of said sacrificial layer comprises the step of blanket depositing said sacrificial layer of highly conductive polysilicon.

4. The method of claim 1, wherein said liner is titanium.

5. The method of claim 4, wherein said depositing of said liner comprises steps selected from the group consisting of
i. sputtering and annealing, and
ii. reactive sputtering and annealing.

6. The method of claim 1, wherein the metal layer is tungsten.

7. The method of claim 1, wherein step (f) is accomplished by etching.

8. The method of claim 2, wherein said sacrificial layer is less than 100 Å thick.

9. The method of claim 3, wherein said sacrificial layer is less than 100 Å thick.

10. A semiconductor device having at least one interconnect structure fabricated according to the method of claim 1.

11. A process integration scheme for fabricating semiconductor devices including the method of claim 1.
